(19) United States
(12) Patent Application Publication
(10) Pub. No.: US 2024/0429888 A1
(43) Pub. Date: Dec. 26, 2024

(54) VARIABLE GAIN AMPLIFIER WITH COMPLEMENTARILY SWITCHED NEUTRALIZED DIFFERENTIAL PAIR

(71) Applicant: Intel Corporation, Santa Clara, CA (US)

(72) Inventors: Ritesh Bhat, Portland, OR (US); Steven Callender, Denver, CO (US); Peter Baumgartner, Munich (DE)

(73) Assignee: Intel Corporation, Santa Clara, CA (US)

(21) Appl. No.: 18/212,308

(22) Filed: Jun. 21, 2023

(51) Int. Cl. H03F 3/45; H03G 1/00; H03G 3/00

(52) U.S. Cl. CPC H03F 3/45264; H03G 1/0029; H03G 3/001

(57) ABSTRACT

An integrated circuit device includes a variable gain amplifier with multiple gain circuits coupled in parallel, where one or more of the multiple gain circuits comprises a first differential pair of transistors, and a complementarily switched second differential pair of transistors cross-connected to the first differential pair of transistors with a sign inversion relative to the first differential pair of transistors. Other examples are disclosed and claimed.

### BACKGROUND

A differential amplifier amplifies the difference between two input voltages. In some circuits, a differential pair amplifier may be implemented with two three-terminal transistor devices with two inputs and two outputs, where the two control terminals (e.g., the base of a bipolar junction transistor, the gate of a field effect transistor, etc.) are coupled to the two inputs that are differentially amplified to provide the differential output. A differential pair amplifier may be utilized as one stage of a multi-stage amplifier such as a variable gain amplifier. Such variable gain amplifiers may be utilized in a wide variety of electronic devices including integrated circuits, transmitters, receivers, etc.

There is an ongoing need for improved computational devices to enable ever increasing demand for modeling complex systems, providing reduced computation times, and other considerations. In some contexts, scaling features of integrated circuits has been a driving force for such improvements. Other advancements have been made in materials, device structure, circuit layout, and so on. In particular, there is an ongoing desire to improve variable gain amplifiers that are utilized for, in, or otherwise support operation of integrated circuits. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1A illustrates a block diagram of an example variable gain amplifier that includes one or more complementary switched gain circuits;

FIG. 1B illustrates a block diagram of another example variable gain amplifier that includes one or more complementary switched gain circuits;

FIG. 2 illustrates a block diagram of an example of an IC device that includes a variable gain amplifier with complementary switched neutralized differential pairs (NDPs);

FIGS. 3A to 3B illustrate example operating states for operation of a slice in a and example variable gain amplifier array;

FIG. 4 illustrates a circuit diagram of another example of a complementary switched NDP slice;

FIG. 5 illustrates a circuit diagram of another example of a complementary switched NDP slice;

FIG. 6 illustrates a block diagram of an example of a hybrid variable gain amplifier that includes a complementary switched NDP array;

FIG. 7 illustrates a block diagram of a system that includes a variable gain amplifier with complementary switched NDPs;

FIG. 8 illustrates a diagram of an example data server machine employing an IC device with a variable gain amplifier with complementarily switched NDPs; and

FIG. 9 is a block diagram of an example computing device, all in accordance with at least some implementations of the present disclosure.

### DETAILED DESCRIPTION

In the following detailed description, reference is made to the accompanying drawings that show, by way of illustration, specific examples in which the claimed subject matter may be practiced. These examples are described in sufficient detail to enable those skilled in the art to practice the subject matter. The various examples, although different, are not necessarily mutually exclusive. For example, a particular feature, structure, or characteristic described herein, in connection with one example, may be implemented within other examples without departing from the spirit and scope of the claimed subject matter.

References within this specification to “one example” or “an example” mean that a particular feature, structure, or characteristic described in connection with the example is included in at least one implementation encompassed within the present description. Therefore, the use of the phrase “one example” or “in an example” does not necessarily refer to the same example. In addition, the location or arrangement of individual elements within each disclosed example may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular examples, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, examples are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Integrated transmitters and receivers may utilize amplifier chains with electronically-controlled gain in order to improve a link error vector magnitude (EVM) under various channel loss conditions and to compensate for process, voltage, and temperature (PVT) variations. Preferably, only the gain is changed through the chain while other performance metrics of the amplifier chain (e.g., bandwidth, linearity, etc.) are preserved. A problem with conventional variable gain amplifiers, particularly at higher operating frequencies, is that changing the gain may affect other performance characteristics. In particular, nodal impedances may be more difficult to control and may have increased sensitivity to parasitics at millimeter wave (mmWave) frequencies (e.g., twenty eight (28) gigahertz (GHz), above thirty (30) GHz) and sub-terahertz (subTHz) frequencies (e.g., between 100 GHz and 300 GHz).

In some systems, gain control is performed in the baseband circuits of transmitters and receivers by varying bias currents or switching losses. A problem is that gain control using baseband circuits has limited utility in transmitter and receiver chains. In transmitters, baseband gain control does not scale the local oscillator (LO) leakage signal with the power of the desired signal thereby causing significant signal-to-noise (SNR) hit at low gain settings where the signal level can be lower than LO leakage present at a radio frequency (RF) output port. In receivers, delaying gain control to the baseband stage means that all preceding blocks will be exposed to higher than desirable signal swings under certain channel conditions. Such delayed gain control impacts the SNR of the signal before it reaches the baseband due to nonlinearities in the low-noise amplifier (LNA), mixers, and any active block placed before gain control.

At mmWave frequencies, switchable lossy auxiliary lines that are coupled to the matching networks of an amplifier stage may be utilized to vary the insertion loss of the matching network, and hence vary the gain of the amplifier as desired. A problem is that switchable lossy auxiliary lines may result in a variation of the input and output impedance of the matching network with gain state, thereby changing the overall frequency response of the chain. Moreover, varying the insertion loss may increase the baseline insertion loss of the matching network when compared to the loss of the original matching network without this gain control mechanism.

In some systems, amplifier stages are designed using switchable arrays of devices where the switches turn on or off the direct current (DC) current into each slice of the array. The gain of the amplifier stage is set depending on the number of slices in the array that have DC current passing through the slices. A problem is that when amplifier stages comprised of arrays of switchable devices (differential pairs or neutralized differential pairs) are used, the OFF devices have a significantly different input and output impedance compared to an ON device. The different impedance causes the quality of the impedance match at the input and output to vary, typically degrading with lower gain settings. The impedance mismatch causes the overall frequency response and bandwidth to significantly degrade as lower gain settings are exercised.

In some systems, mmWave attenuator structures are designed using switchable T or Pi sections that preserve impedance matching at their interfaces. While attenuator structures preserve the input and output interface matching conditions across gain states, a problem is that the attenuator structures can be massive structures occupying areas equivalent to the amplification stages (e.g., or even more area). For example, the parasitics of each switch in the structure (e.g., at least two switches per Pi or T section) needs be resonated out by an accompanying inductor. Another problem is that such attenuator structures may be fairly narrowband and lossy. Another problem is that such attenuator structures may be difficult to apply at mmWave and subTHz frequencies due to parasitic component values being comparable to desired component values severely complicating the design and increasing the baseline insertion loss.

Some examples may overcome one or more of the foregoing problems. Some examples may provide gain control technology within an amplifier stage that preserves the input and output impedances as well as transfer function across gain stages. Some examples may also improve the linearity of the stage at lower gain settings. Some examples may utilize differential stages with neutralization. Some examples may utilize an array of switchable differential pairs where each switchable differential pair has another complementarily switched differential pair with outputs that are connected to the first differential pair with a sign inversion. As used herein, “complement” refers to Boolean operations and expressions where the complement refers to the inverse or opposite. For example, the complement of the variable A is NOT A. If A=1, then NOT A=0. If A=0, then NOT A=1. Generally, the complement of a variable may be indicated by a bar over the variable (overbar). As used herein, complementary switching of two switches generally indicates that if one switch is ON then the other switch is OFF.

Some examples may provide a broadband variable gain amplifier that utilizes the array of switchable differential pairs and complementarily switched differential pairs in parallel with a fixed and non-switchable capacitively neutralized differential pair. In some implementations, the complementary switching and symmetry of the circuit ensures that the input and output matching conditions are closely preserved across gain states while having a wide gain control range.

As used herein, a transistor refers to a three or more terminal device where a voltage or current at a control terminal controls the electrical behavior of two non-control terminals. In some examples, a field effect transistor (FET) may be utilized where a voltage on a gate terminal controls current between a drain terminal and a source terminal. In some examples, a bipolar junction transistor (BJT) may be utilized where a current on a base terminal controls current between a collector terminal and an emitter terminal. Those skilled in the art will appreciate that although examples are described herein that utilize FETs, equivalent examples may be implemented with BJTs. In general, for some implementations, the gate, drain, and source terminals of a FET may be considered respectively analogous to the base, collector, and emitter terminals of a BJT. Some examples are described herein as implemented in complementary metal-oxide semiconductor (CMOS) technology, but other examples may extend to any integrated technology (e.g., gallium nitride (GaN), silicon germanium (SiGe), etc.).

Advantageously, some examples may provide a compact (e.g., area-efficient), broadband, and high dynamic range RF attenuator that is effective at both traditional RF (e.g., sub-6 GHz) and mmWave/subTHz frequencies (e.g., 28+ GHz). Another advantage in some examples is that both bandwidth and amplifier center frequency tuning are well preserved across all gain states. Another advantage is that some examples may provide gain control in the RF sections of transmit and receive chains. Another advantage is that some examples may provide gain control technology without increasing the baseline loss.

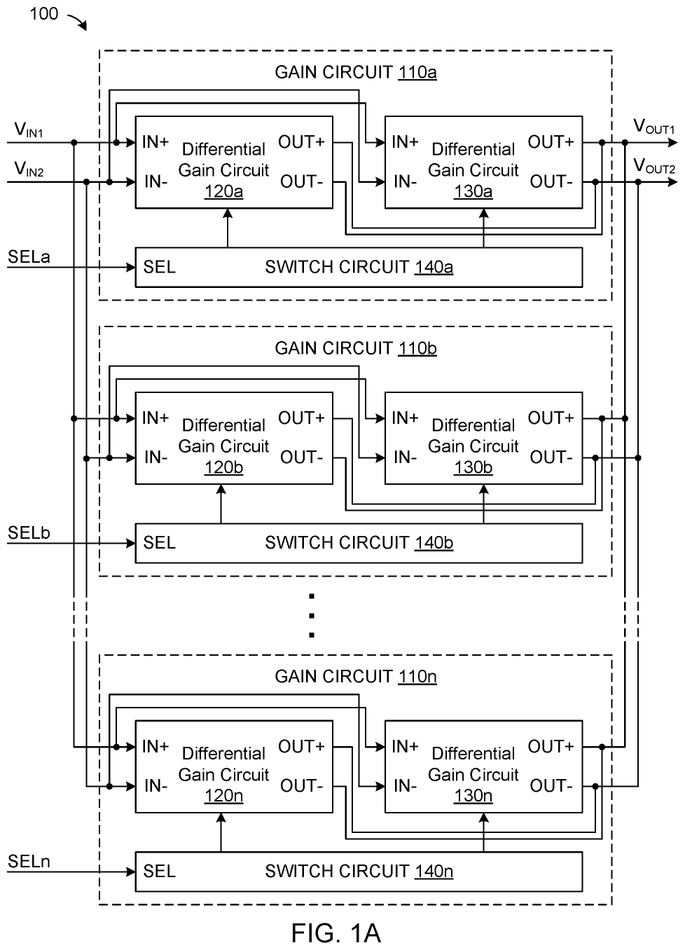

FIG. 1A shows an illustrative block diagram of an example variable gain amplifier 100, that includes multiple gain circuits 110a through 110n (collectively “110”) coupled in parallel. In some examples, the gain circuits 110 comprise respective first differential gain circuits 120a through 120n (collectively “120”) respectively coupled to a first differential input V_{IN1}, a second differential input V_{IN2} (e.g., that is 180 degrees out of phase with respect to the first differential input V_{IN1}), a first differential output V_{OUT1}, and a second differential output V_{OUT2} (e.g., that is 180 degrees out of phase with respect to the first differential output V_{OUT1}), respective second differential gain circuits 130a through 130n (collectively “130”) cross-connected with the first differential gain circuits 120, and respective switch circuits 140a through 140n (collectively “140”) coupled to the first and second differential gain circuits 120, 130 to selectively activate (e.g., turn on a differential pair of transistors in) only one of the first and second differential gain circuits 120, 130 in a particular gain circuit 110 (e.g., via selection signals SELa through SELn).

As used herein, cross-connected refers to a sign inversion between the two differential gain circuits that may be implemented at either the inputs or outputs. As shown in FIG. 1A, the respective second differential gain circuits 130 are coupled in parallel with the first differential input V_{IN1} and the second differential input V_{IN1} (e.g., IN+ of the first differential gain circuits 120 coupled to IN+ of the second differential gain circuits 130, and IN− of the first differential gain circuits 120 coupled to IN− of the second differential gain circuits 130), and coupled with the first and second differential outputs V_{OUT1}, V_{OUT2} reversed with respect to the first differential gain circuits 120 (e.g., OUT+ of the first differential gain circuits 120 coupled to OUT− of the second differential gain circuits 130, and OUT− of the first differential gain circuits 120 coupled to OUT+ of the second differential gain circuits 130).

FIG. 1B shows an illustrative block diagram of an example variable gain amplifier 150 with similar elements to the variable gain amplifier 100 labelled with like reference numerals from FIG. 1A. As shown in FIG. 1B, the respective second differential gain circuits 130 coupled in parallel with the first differential output V_{OUT1} and the second differential output V_{OUT2} (e.g., OUT+ of the first differential gain circuits 120 coupled to OUT+ of the second differential gain circuits 130, and OUT− of the first differential gain circuits 120 coupled to OUT− of the second differential gain circuits 130), and coupled with the first and second differential inputs V_{IN1}, V_{IN2} reversed with respect to the first differential gain circuits 120 (e.g., IN+ of the first differential gain circuits 120 coupled to IN− of the second differential gain circuits 130, and IN− of the first differential gain circuits 120 coupled to IN+ of the second differential gain circuits 130).

For some examples of either of the variable gain amplifiers 100, 150, the second differential gain circuits 130 may respectively provide neutralization for the corresponding first differential gain circuits 120, the switch circuits 140 may be further configured to set the corresponding second differential gain circuits 130 in either a cutoff mode or a saturation mode, an operational frequency of the variable gain amplifier may be in excess of 10 GHz (e.g., mmWave, subTHz, etc.), and/or the switch circuits 140 may respectively comprise a first tail switch controllable by respective first switch signals (not shown; e.g., SWa through SWn; collectively “SW”) and respectively coupled the first differential gain circuit 120, and a second tail switch controllable by respective second switch signals (not shown; e.g., NOT_SWa through NOT_SWn; collectively “NOT_SW”) and respectively coupled to the second differential gain circuits 130, where the second switch signals (e.g., NOT_SW) are complements of the corresponding first switch signals (e.g., SW).

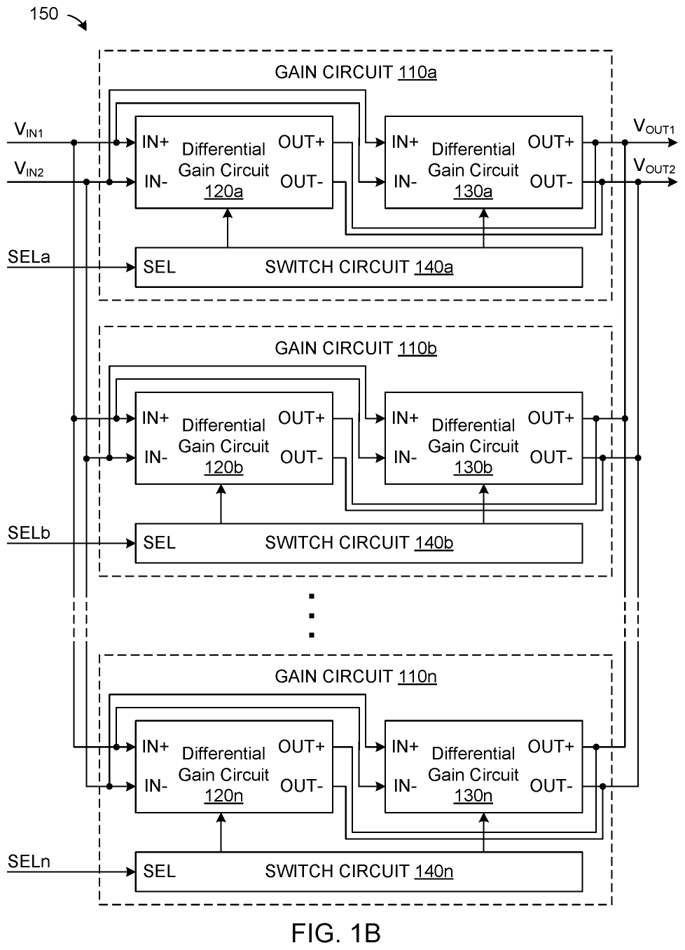

FIG. 2 shows an illustrative block diagram of an example IC device 200 that includes a variable gain amplifier 210 with multiple gain circuits 215a through 215n (collectively “gain circuits 215) coupled in parallel (e.g., where in(+) and in(−) are supplied to each slice or stage, and where out(+) and out(−) are provided from each slice or stage), where one or more of the multiple gain circuits 215 comprises a first differential pair of transistors (e.g., M1 and M2), and a complementary switched second differential pair of transistors (e.g., M4 and M5) cross-connected to the first differential pair of transistors M1, M2 with a sign inversion relative to the first differential pair of transistors M1, M2. In this example, the first and second differential pairs of transistors are in a neutralized differential pair topology. For example, the variable gain amplifier 210 may comprise an array of complementary switched MOS neutralized differential pairs (NDPs).

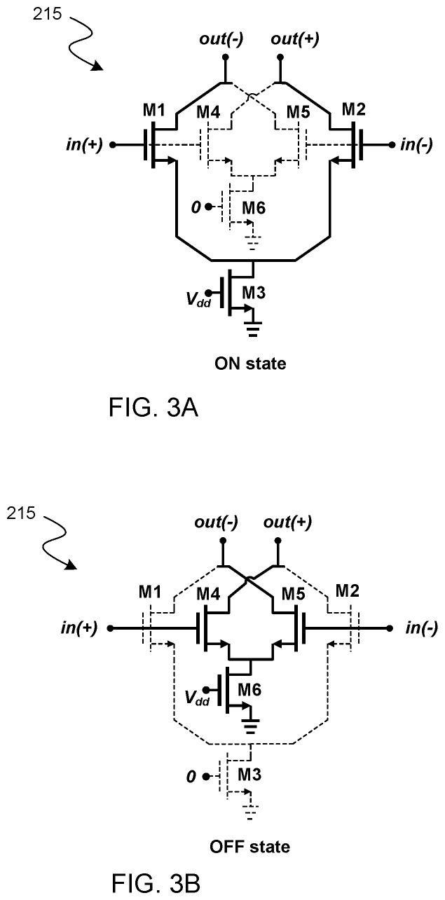

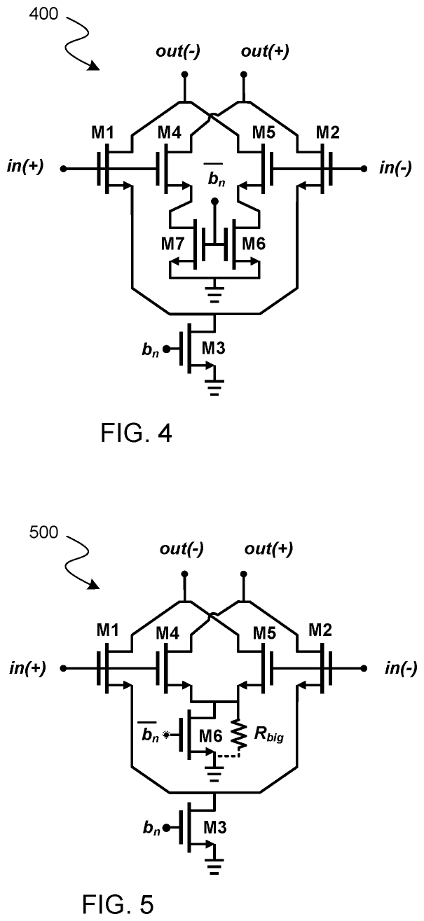

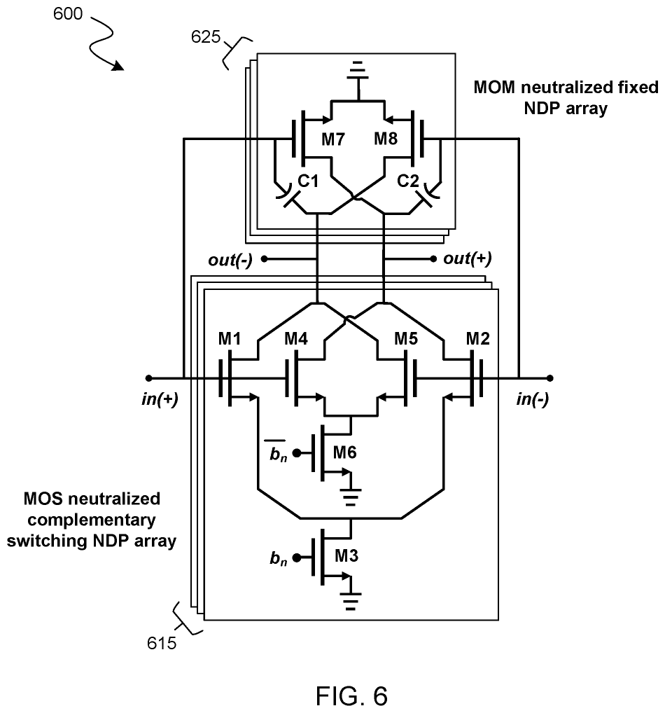

In some examples, a first tail switch transistor M3 controllable by a first switch signal bₙ may be coupled between the first differential pair of transistors M1, M2 and ground, and a second tail switch transistor M6 controllable by a second switch signal not_bₙ may be coupled between the second differential pair of transistors M4, M5 and ground, where the second switch signal not_b₁ is a complement of the first switch signal bₙ. (e.g., to provide the complementary switching for the first and second differential pairs of transistors). In some examples, a third tail switch transistor controllable by the second switch signal not_bₙ may be coupled between the second differential pair of transistors M4, M5 and ground (e.g., see FIG. 4). In some examples, a shunt resistor may be coupled in parallel with the second tail switch transistor M6 (e.g., see FIG. 5). In some examples, a third fixed and non-switchable capacitively neutralized differential pair of transistors may be coupled in parallel with the first and second differential pairs of transistors (e.g., see FIG. 6). In any of the examples herein, an operational frequency of the variable gain amplifier 210 may be in excess of 10 GHz (e.g., mmWave, subTHz, etc.).

Some examples may provide variable gain neutralized differential amplifier technology. For a mmWave or subTHz transmit or receive chain, some examples may reduce or eliminate the need for large passive attenuators between amplifier stages. Some examples may further reduce or eliminate the need for transformers and T-lines with leaky parasitic auxiliary lines. In some examples, device level connections for differential devices in the same diffusion may have a shared connection on the positive and negative input gate path while the drain diffusions may have an inverting connection.

As illustrated in FIG. 2, each of the gain circuits 215 may be considered a slice of a variable gain amplifier array. Each slice of the array includes a first differential pair (M1, M2; e.g., also referred to as main differential pair or outer differential pair) with a switch (M3) connected to the source terminals of the first differential pair, and a cross-connected second differential pair (M4, M5; with an output drain connection that is inverted with respect to the first differential pair; e.g., also referred to as inner differential pair, neutralizing differential pair, or complementary switched differential pair) with a separate switch (M6) connected to the source terminals of the second differential pair (M4, M5). The transistors M4, M5 are sized to primarily compensate for the imaginary part of the feedback y-parameter (IM{Y12}) of the transistors M1, M2 (e.g., in a neutralization arrangement) and to increase amplifier gain for a high frequency design. In other implementations of metal-oxide semiconductor (MOS) neutralized differential pairs, the neutralizing devices (e.g., M4, M5) are always in the cutoff region of operation so that there is minimal gain reduction of the main differential pair device (e.g., M1, M2). In some examples of a variable gain amplifier with complementary switch differential pairs, however, the neutralizing differential pair device (e.g., M4, M5) is reconfigurable to be in either cutoff or saturation mode via the use of the tail switch device (e.g., M6). When in saturation mode, the neutralizing differential pair device (e.g., M4, M5) can perform normal signal amplification but with an opposite phase when compared to the main differential pair (e.g., M1, M2).

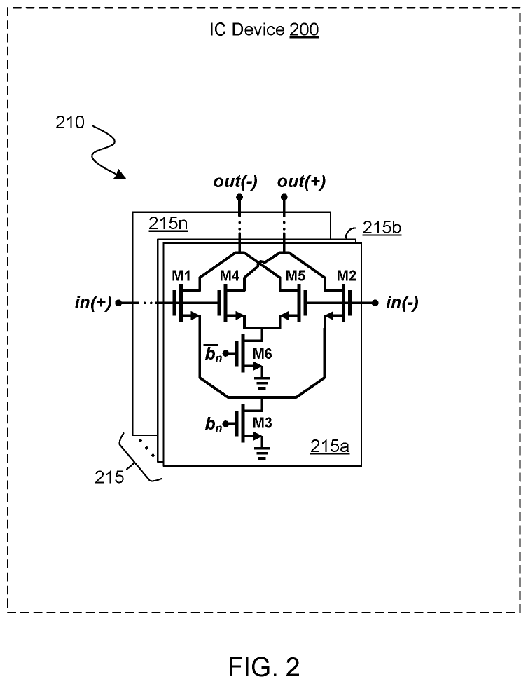

FIGS. 3A and 3B show two example operating states for operation of a single amplifier slice (e.g., a single gain circuit 215) in the variable gain amplifier array 210. In the ON state (FIG. 3A), the tail switch M3, that is connected to the common source node of the outer differential pair (M1, M2), is turned ON and results in amplification of the input signal present at the in(+) and in(−) terminals. In addition, the tail switch (M6) of the inner differential pair (M4, M5) is turned OFF and hence the differential pair device neutralizes the feedback component (Cgd) of the outer differential pair (M1, M2). In the ON state, the inner differential pair (M4, M5) may improve stability and boost gain (e.g., a benefit of neutralization), and do not contribute to any amplification of the input signal present at the gate terminals of the inner differential pair (M4, M5).

In the OFF state (FIG. 3B), however, the outer differential pair (M1, M2) are in their cutoff regions and the inner differential pair (M4, M5) are turned ON. In this configuration, the inner differential pair (M4, M5) provide amplification of the input signal but with an inverted polarity with respect to the ON state. The outer differential pair is turned OFF and neutralizes the inner differential pair without contributing to amplification of the input signal. With this configuration and operation, the amplifier slice 215 can invert the polarity of the gain of the amplifier slice 215, keeping magnitude of the gain constant and substantially preserving the exact same level of neutralization as performed by OFF devices. As a result, any OFF slice can be used to cancel the gain of an ON slice and thereby be used for gain control. Starting with an array of the amplifier slices 215 all in the ON state, a neutralized amplifier with maximum gain state is achieved. The gain of the variable gain amplifier can then be reduced as more slices are configured in the OFF state, reaching theoretical zero gain when the number of OFF devices equals the number of ON devices yielding a potential for high dynamic range in gain control that is valuable for system-level control. Additionally, the symmetry of the amplifier slice 215, in either an ON or OFF state, allows the input and output impedance of the array to stay almost constant across various gain configurations preserving amplifier frequency response across gain states.

FIG. 4 shows another example of a complementary switched MOS NDP slice 400. In FIG. 4, the inner differential pair (M4, M5) have their sources separated and degenerated with an additional tail switch transistor M7. Advantageously, degenerating the source nodes of the inner differential pair separately may further reduce any residual gain in the OFF state. Some examples may alternatively utilize two tail switch transistors on the outer differential pair, or on both the inner and outer differential pairs.

FIG. 5 shows another example of a complementary switched MOS NDP slice 500. In FIG. 5, the tail switch transistor M6 is in shunt with a resistor R_{big} (e.g., with nominally high impedance). Some examples may alternatively utilize a shunt resistor on the outer differential pair, or on both the inner and outer differential pairs. Those skilled in the art will appreciate that numerous other NDP topologies may be adapted with examples of the complementary switching described herein. Given the benefit of the present description and drawings, a wide variety of unit cell neutralization topologies may be readily extended to a complementary switching topology as described herein.

As compared to a metal-oxide-metal (MOM) capacitor NDP array (e.g., where capacitors are cross-connected with a differential pair of transistors to provide neutralization) and a MOS NDP array where the source nodes of the inner differential pair are coupled directly to ground (e.g., without the complementary switching provided by the second tail switch M6), a variable gain array that utilizes examples of the complementary switched NDP array as described herein may demonstrate improved performance, particularly at higher frequencies and/or lower gain settings. For example, a MOM NDP array without complementary switching as described herein may exhibit significant variation in input and output matching, and the MOS NDP array may exhibit variation mostly in tuning of the frequency response. Advantageously, examples of a MOS NDP array with complementary switching may exhibit almost no variation in shape nor tuning of the frequency response.

Another benefit of the examples of a MOS NDP array with complementary switching is the improvement in linearity especially in lower gain states. The OFF slices in an example amplifier array may generate linear and nonlinear components that are opposite in phase to those generated by the ON slices for the odd-order components. While the OFF slices cancel out the main signal components, the OFF slices also cancel the nonlinear components. In some examples, only the nonlinear components generated at the input of the differential pair are cancelled but those generated at the output are not cancelled but add in phase. Other variable gain amplifier technology may not provide such cancellation of nonlinearity. In comparison to a MOM NDP array and a MOS NDP array without complementary switching as described herein, some examples may provide substantial improvement in third order intercept power (OIP3) at low gain states that may translates to significant improvement in signal to noise and distortion ratio (SNDR).

FIG. 6 shows an example of a hybrid variable gain amplifier 600 that includes a combination of a complementary switched NDP array 615 coupled in parallel with a MOM NDP array 625. The complementary switched NDP array 615 may have any useful unit cell neutralization topologies such as, for example, the topology of the gain circuits 215 (FIG. 2). Similarly, the MOM NDP array 625 may have any useful topologies such as, for example, respective third differential pairs of transistors (M7, M8) with respective cross-connected capacitors (C1, C2), coupled as shown. Although three slices are shown, other examples of the amplifier 600 may have more or fewer slices and the number of slices of each type of array 615, 625 may be different from each other.

MOS-based neutralized variable gain amplifiers tend to be more narrowband as compared to MOM capacitor-based neutralized variable gain amplifiers. The amplifier 600 may leverage the advantages of the wideband matching of MOM NDP arrays complementary switched NDP arrays in a hybrid variable gain amplifier where, for example, up to half of the number of slices in the array are composed of the complementary switched NDP slices and the remaining slices are MOM neutralized differential pairs without tail switches. Advantageously, examples of the hybrid variable gain amplifier 600 may substantially improve the bandwidth of the matching network, as compared to a fully MOS-based NDP array with complementary switching, while the tuning of the center frequency of match does not change with gain state. In some examples, S21 also shows negligible change in shape or tuning with gain state (e.g., other than a lowest gain state that may not likely be used in practical applications). Some examples of the hybrid variable gain amplifier 600 may achieves a peak linearity close to that of a MOM NDP-based array while retaining most of the linearity benefits of the complementary switched NDP array at lower gain states (e.g., significant benefits of both technologies).

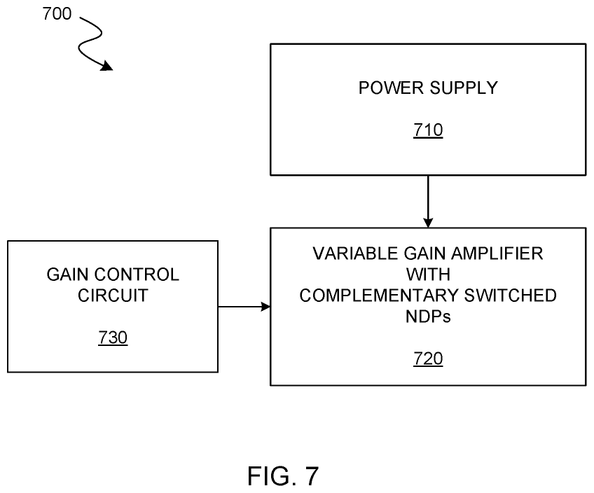

FIG. 7 shows a block diagram of an example of a system 700 that includes a power supply 710 and a variable gain amplifier 720 coupled to the power supply. The variable gain amplifier 720 may include one or more aspects of any of the examples described herein including, for example, one or more slices of complementary switched NDPs. The system 700 may further include a gain control circuit 730 to selectively provide respective switch signals to respective slices of the variable gain amplifier 720 based on an amount of gain to be provided by the variable gain amplifier 720.

In some examples, one or more slices of the variable gain amplifier 720 may include first, second, third, and fourth transistors, each with respective control terminals, first non-control terminals, and second non-control terminals. The respective control terminals of the first and third transistors may be coupled to a first differential input, and respective control terminals of the second and fourth transistors coupled to a second differential input (e.g., that is 180 degrees out of phase with respect to the first differential input), and the respective first non-control terminals of the first and fourth transistors coupled to a first differential output, and respective first non-control terminals of the second and third transistors coupled to a second differential output (e.g., that is 180 degrees out of phase with respect to the first differential output). (e.g., see M1, M2, M4, and M5 in any of FIGS. 2-6). The respective second non-control terminals of the first and second transistors may be coupled to ground through a first switch circuit that is to be controlled by a first switch signal, and the respective second non-control terminals of the third and fourth transistors may be coupled to ground through a second switch circuit that is to be controlled by a second switch signal that is a complement of the first switch signal.

In some examples, the first switch circuit may comprise a fifth transistor with a control terminal of the fifth transistor coupled to the first switch signal, a first non-control terminal of the fifth transistor coupled to the respective second non-control terminals of the first and second transistors, and a second non-control terminal of the fifth transistor coupled to ground (e.g., see M3 in FIG. 2), and the second switch circuit may comprise a sixth transistor with a control terminal of the sixth transistor coupled to the second switch signal, a first non-control terminal of the sixth transistor coupled to the respective second non-control terminals of the third and fourth transistors, and a second non-control terminal of the sixth transistor coupled to ground (e.g., see M6 in FIG. 2).

In some examples, the second switch circuit may further comprise a seventh transistor with a control terminal of the seventh transistor coupled to the second switch signal, a first non-control terminal of the seventh transistor coupled to the respective second non-control terminals of the third and fourth transistors, and a second non-control terminal of the seventh transistor coupled to ground (e.g., see M7 in FIG. 4). In some examples, the second switch circuit may further comprise a high-impedance resistor coupled between the first non-control terminal of the sixth transistor and ground (e.g., see FIG. 5).

In some examples, one or more slices of the variable gain amplifier may further comprise eighth and ninth transistors (e.g., see M7, M8 in FIG. 6), each with respective control terminals, first non-control terminals, and second non-control terminals. A control terminal of the eighth transistors may be coupled to the first differential input, and a control terminal of the ninth transistor may be coupled to the second differential input. A first non-control terminal of the eighth transistor may be coupled to the first differential output, and a first non-control terminal of the ninth transistor may be coupled to the second differential output. Respective second non-control terminals of the eighth and ninth transistors may be coupled to ground. A first capacitor may be coupled between the control terminal of the eighth transistor and the second differential output, and a second capacitor may be coupled between the control terminal of the ninth transistor and the first differential output (e.g., see C1, C2 in FIG. 6).

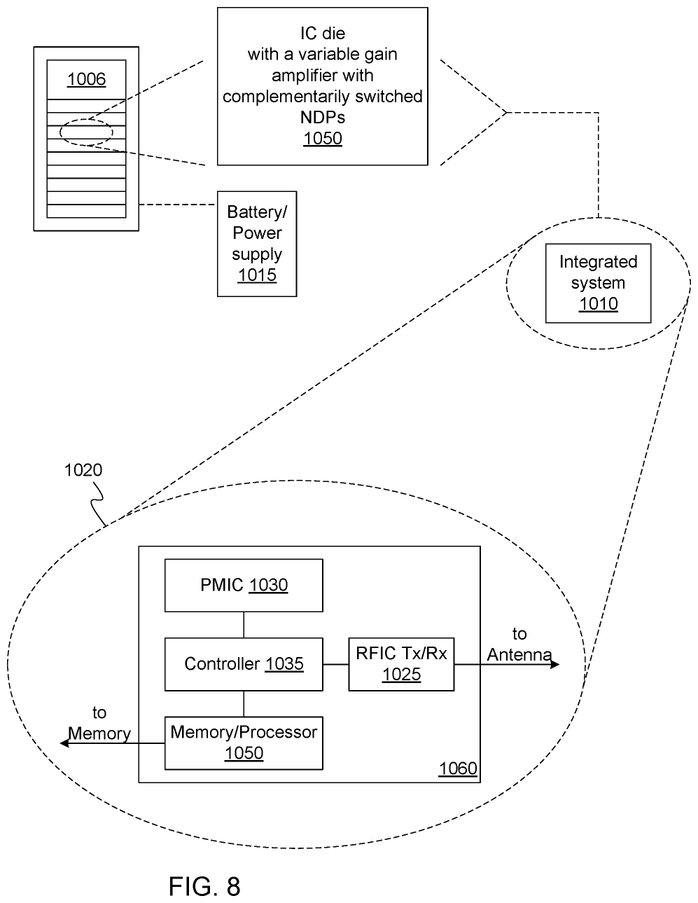

FIG. 8 illustrates a diagram of an example data server machine 1006 employing an IC device 1050 with a variable gain amplifier with complementarily switched NDPs as described herein, in accordance with some examples. Server machine 1006 may be any commercial server, for example, including any number of high-performance computing platforms disposed within a rack and networked together for electronic data processing, that in the exemplary example includes one or more devices 1050 having one or more variable gain amplifier(s) with complementarily switched NDPs.

Also as shown, server machine 1006 includes a battery and/or power supply 1015 to provide power to devices 1050, and to provide, in some examples, power delivery functions such as power regulation. Devices 1050 may be deployed as part of a package-level integrated system 1010. Integrated system 1010 is further illustrated in the expanded view 1020. In the exemplary example, devices 1050 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an example, device 1050 is a microprocessor including a cache memory. As shown, device 1050 may be a multi-chip module employing one or more IC devices with one or more variable gain amplifier(s) with complementarily switched NDPs, as discussed herein. Device 1050 may be further coupled to (e.g., communicatively coupled to) a board, an interposer, or a substrate 1060 along with, one or more of a power management IC (PMIC) 1030, RF (wireless) IC (RFIC) 1025 (e.g., that may also include one or more variable gain amplifier(s) with complementarily switched NDPs), including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In some examples, RFIC 1025, PMIC 1030, controller 1035, and device 1050 include IC devices having a variable gain amplifier with complementarily switched NDPs on substrate 1060 in a multi-chip module.

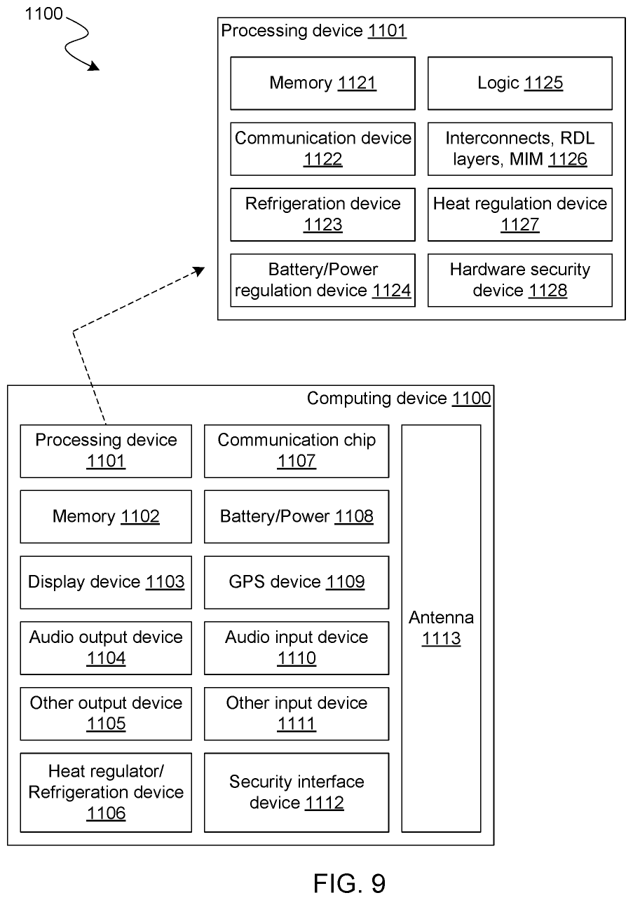

FIG. 9 is a block diagram of an example computing device 1100, in accordance with some examples. For example, one or more components of computing device 1100 may include any of the devices or structures discussed herein. A number of components are illustrated in FIG. 9 as being included in computing device 1100, but any one or more of these components may be omitted or duplicated, as suitable for the application. In some examples, some or all of the components included in computing device 1100 may be attached to one or more printed circuit boards (e.g., a motherboard). In some examples, various ones of these components may be fabricated onto a single system-on-a-chip (SoC) die. Additionally, in various examples, computing device 1100 may not include one or more of the components illustrated in FIG. 9, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, that may itself include one or more memory devices such as volatile memory (e.g., dynamic random-access memory (DRAM)), nonvolatile memory (e.g., read-only memory (ROM)), flash memory, solid state memory, and/or a hard drive. In some examples, memory 1102 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed herein.

In some examples, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, that is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other examples. Computing device 1100 may include an antenna 1113 to facilitate wireless communications and/or to receive other wireless communications (such as AM or FM radio transmissions).

In some examples, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some examples, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-9. The subject matter may be applied to other transistor applications, as well as any appropriate manufacturing application, as will be understood to those skilled in the art.

The following examples pertain to further examples, and specifics in the examples may be used anywhere in one or more examples.

Example 1 includes a variable gain amplifier, comprising multiple gain circuits coupled in parallel, wherein one or more of the multiple gain circuits comprises a first differential gain circuit coupled to a first differential input, a second differential input, a first differential output, and a second differential output, a second differential gain circuit cross-connected with the first differential gain circuit, and a switch circuit coupled to the first and second differential gain circuits to selectively activate only one of the first and second differential gain circuits.

Example 2 includes the variable gain amplifier of Example 1, wherein the second differential gain circuit is coupled in parallel with the first differential input and the second differential input and coupled with the first and second differential outputs reversed with respect to the first differential gain circuit.

Example 3 includes the variable gain amplifier of Example 1, wherein the second differential gain circuit is coupled in parallel with the first differential output and the second differential output and coupled with the first and second differential inputs reversed with respect to the first differential gain circuit.

Example 4 includes the variable gain amplifier of any of Examples 1 to 3, wherein the second differential gain circuit provides neutralization for the first differential gain circuit.

Example 5 includes the variable gain amplifier of Example 4, wherein the switch circuit is further to set the second differential gain circuit in either a cutoff mode or a saturation mode.

Example 6 includes the variable gain amplifier of any of Examples 1 to 5, wherein the switch circuit comprises a first tail switch controllable by a first switch signal and coupled to the first differential gain circuit, and a second tail switch controllable by a second switch signal and coupled to the second differential gain circuit, wherein the second switch signal is a complement of the first switch signal.

Example 7 includes the variable gain amplifier of any of Examples 1 to 7, wherein an operational frequency of the variable gain amplifier is in excess of ten gigahertz.

Example 8 includes an integrated circuit (IC) device, comprising a variable gain amplifier with multiple gain circuits coupled in parallel, wherein one or more of the multiple gain circuits comprises a first differential pair of transistors, and a complementarily switched second differential pair of transistors cross-connected to the first differential pair of transistors with a sign inversion relative to the first differential pair of transistors.

Example 9 includes the IC device of Example 8, wherein the first and second differential pairs of transistors are in a neutralized differential pair topology.

Example 10 includes the IC device of any of Examples 8 to 9, further comprising a first tail switch transistor controllable by a first switch signal and coupled between the first differential pair of transistors and ground, and a second tail switch transistor controllable by a second switch signal and coupled between the second differential pair of transistors and ground, wherein the second switch signal is a complement of the first switch signal.

Example 11 includes the IC device of Example 10, further comprising a third tail switch transistor controllable by the second switch signal and coupled between the second differential pair of transistors and ground.

Example 12 includes the IC device of Example 10, further comprising a shunt resistor coupled in parallel with the second tail switch transistor.

Example 13 includes the IC device of any of Examples 8 to 12, further comprising a third fixed and non-switchable capacitively neutralized differential pair of transistors coupled in parallel with the first and second differential pairs of transistors.

Example 14 includes the IC device of any of Examples 8 to 13, wherein an operational frequency of the variable gain amplifier is in excess of ten gigahertz.

Example 15 includes a system, comprising a power supply and a variable gain amplifier coupled to the power supply, one or more slices of the variable gain amplifier comprising first, second, third, and fourth transistors, each with respective control terminals, first non-control terminals, and second non-control terminals, respective control terminals of the first and third transistors coupled to a first differential input, and respective control terminals of the second and fourth transistors coupled to a second differential input, respective first non-control terminals of the first and fourth transistors coupled to a first differential output, and respective first non-control terminals of the second and third transistors coupled to a second differential output, respective second non-control terminals of the first and second transistors coupled to ground through a first switch circuit that is to be controlled by a first switch signal, and respective second non-control terminals of the third and fourth transistors coupled to ground through a second switch circuit that is to be controlled by a second switch signal that is a complement of the first switch signal.

Example 16 includes the system of Example 15, wherein the first switch circuit comprises a fifth transistor with a control terminal of the fifth transistor coupled to the first switch signal, a first non-control terminal of the fifth transistor coupled to the respective second non-control terminals of the first and second transistors, and a second non-control terminal of the fifth transistor coupled to ground, and wherein the second switch circuit comprises a sixth transistor with a control terminal of the sixth transistor coupled to the second switch signal, a first non-control terminal of the sixth transistor coupled to the respective second non-control terminals of the third and fourth transistors, and a second non-control terminal of the sixth transistor coupled to ground.

Example 17 includes the system of Example 16, wherein the second switch circuit further comprises a seventh transistor with a control terminal of the seventh transistor coupled to the second switch signal, a first non-control terminal of the seventh transistor coupled to the respective second non-control terminals of the third and fourth transistors, and a second non-control terminal of the seventh transistor coupled to ground.

Example 18 includes the system of Example 16, wherein the second switch circuit further comprises a high-impedance resistor coupled between the first non-control terminal of the sixth transistor and ground.

Example 19 includes the system of any of Examples 15 to 18, wherein one or more slices of the variable gain amplifier further comprises eighth and ninth transistors, each with respective control terminals, first non-control terminals, and second non-control terminals, a control terminal of the eighth transistors coupled to the first differential input, and a control terminal of the ninth transistor coupled to the second differential input, a first non-control terminal of the eighth transistor coupled to the first differential output, and a first non-control terminal of the ninth transistor coupled to the second differential output, respective second non-control terminals of the eighth and ninth transistors coupled to ground, a first capacitor coupled between the control terminal of the eighth transistor and the second differential output, and a second capacitor coupled between the control terminal of the ninth transistor and the first differential output.

Example 20 includes the system of any of Examples 15 to 19, further comprising a gain control circuit to selectively provide respective switch signals to respective slices of the variable gain amplifier based on an amount of gain to be provided by the variable gain amplifier.

Example 21 includes the system of any of Examples 15 to 20, wherein an operational frequency of the variable gain amplifier is in excess of ten gigahertz.

Example 22 includes an apparatus, comprising first means for amplifying a difference between two input voltages to provide a differential output, second means for amplifying the difference between the two input voltages to provide the differential output, means for cross-connecting respective inputs and outputs of the first and second means with a sign inversion with respect to each other, and means for complementary switching the first and second means.

Example 23 includes the apparatus of Example 22, wherein the second means further comprises means for neutralizing the first means.

Example 24 includes the apparatus of any of Examples 22 to 23, further comprising means for preserving an input impedance of the first and second means across gain stages.

Example 25 includes the apparatus of any of Examples 22 to 24, further comprising means for preserving an output impedance of the first and second means across gain stages.

Example 26 includes the apparatus of any of Examples 22 to 25, further comprising means for preserving a transfer function of the first and second means across gain stages.

Example 27 includes the apparatus of any of Examples 22 to 26, further comprising means for maintaining a linearity of the first and second means across gain stages at lower gain settings.

Example 28 includes the apparatus of any of Examples 22 to 27, further comprising third non-switched means for amplifying the difference between the two input voltages to provide the differential output, wherein the third means is coupled in parallel with the first and second means.

The disclosure can be practiced with modification and alteration, and the scope of the appended claims is not limited to the examples so described. For example, the above examples may include specific combinations of features. However, the above examples are not limiting in this regard and, in various implementations, the above examples may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. A variable gain amplifier, comprising multiple gain circuits coupled in parallel, wherein one or more of the multiple gain circuits comprises:
a first differential gain circuit coupled to a first differential input, a second differential input, a first differential output, and a second differential output;
a second differential gain circuit cross-connected with the first differential gain circuit; and
a switch circuit coupled to the first and second differential gain circuits to selectively activate only one of the first and second differential gain circuits.

2. The variable gain amplifier of claim 1, wherein the second differential gain circuit is coupled in parallel with the first differential input and the second differential input and coupled with the first and second differential outputs reversed with respect to the first differential gain circuit.

3. The variable gain amplifier of claim 1, wherein the second differential gain circuit is coupled in parallel with the first differential output and the second differential output and coupled with the first and second differential inputs reversed with respect to the first differential gain circuit.

4. The variable gain amplifier of claim 1, wherein the second differential gain circuit provides neutralization for the first differential gain circuit.

5. The variable gain amplifier of claim 4, wherein the switch circuit is further to set the second differential gain circuit in either a cutoff mode or a saturation mode.

6. The variable gain amplifier of claim 1, wherein the switch circuit comprises:
a first tail switch controllable by a first switch signal and coupled to the first differential gain circuit; and
a second tail switch controllable by a second switch signal and coupled to the second differential gain circuit, wherein the second switch signal is a complement of the first switch signal.

7. The variable gain amplifier of claim 1, wherein an operational frequency of the variable gain amplifier is in excess of ten gigahertz.

8. An integrated circuit (IC) device, comprising a variable gain amplifier with multiple gain circuits coupled in parallel, wherein one or more of the multiple gain circuits comprises:
a first differential pair of transistors; and
a complementarily switched second differential pair of transistors cross-connected to the first differential pair of transistors with a sign inversion relative to the first differential pair of transistors.

9. The IC device of claim 8, wherein the first and second differential pairs of transistors are in a neutralized differential pair topology.

10. The IC device of claim 8, further comprising:
a first tail switch transistor controllable by a first switch signal and coupled between the first differential pair of transistors and ground; and
a second tail switch transistor controllable by a second switch signal and coupled between the second differential pair of transistors and ground, wherein the second switch signal is a complement of the first switch signal.

11. The IC device of claim 10, further comprising:
a third tail switch transistor controllable by the second switch signal and coupled between the second differential pair of transistors and ground.

12. The IC device of claim 10, further comprising:
a shunt resistor coupled in parallel with the second tail switch transistor.

13. The IC device of claim 8, further comprising:
a third fixed and non-switchable capacitively neutralized differential pair of transistors coupled in parallel with the first and second differential pairs of transistors.

14. The IC device of claim 8, wherein an operational frequency of the variable gain amplifier is in excess of ten gigahertz.

15. A system, comprising a power supply and a variable gain amplifier coupled to the power supply, one or more slices of the variable gain amplifier comprising:
first, second, third, and fourth transistors, each with respective control terminals, first non-control terminals, and second non-control terminals;
respective control terminals of the first and third transistors coupled to a first differential input, and respective control terminals of the second and fourth transistors coupled to a second differential input;
respective first non-control terminals of the first and fourth transistors coupled to a first differential output, and respective first non-control terminals of the second and third transistors coupled to a second differential output;
respective second non-control terminals of the first and second transistors coupled to ground through a first switch circuit that is to be controlled by a first switch signal; and
respective second non-control terminals of the third and fourth transistors coupled to ground through a second switch circuit that is to be controlled by a second switch signal that is a complement of the first switch signal.

16. The system of claim 15, wherein the first switch circuit comprises a fifth transistor with a control terminal of the fifth transistor coupled to the first switch signal, a first non-control terminal of the fifth transistor coupled to the respective second non-control terminals of the first and second transistors, and a second non-control terminal of the fifth transistor coupled to ground, and wherein the second switch circuit comprises a sixth transistor with a control terminal of the sixth transistor coupled to the second switch signal, a first non-control terminal of the sixth transistor coupled to the respective second non-control terminals of the third and fourth transistors, and a second non-control terminal of the sixth transistor coupled to ground.

17. The system of claim 16, wherein the second switch circuit further comprises a seventh transistor with a control terminal of the seventh transistor coupled to the second switch signal, a first non-control terminal of the seventh transistor coupled to the respective second non-control terminals of the third and fourth transistors, and a second non-control terminal of the seventh transistor coupled to ground.

18. The system of claim 16, wherein the second switch circuit further comprises a high-impedance resistor coupled between the first non-control terminal of the sixth transistor and ground.

19. The system of claim 15, wherein one or more slices of the variable gain amplifier further comprises:
eighth and ninth transistors, each with respective control terminals, first non-control terminals, and second non-control terminals;
a control terminal of the eighth transistors coupled to the first differential input, and a control terminal of the ninth transistor coupled to the second differential input;
a first non-control terminal of the eighth transistor coupled to the first differential output, and a first non-control terminal of the ninth transistor coupled to the second differential output;
respective second non-control terminals of the eighth and ninth transistors coupled to ground;
a first capacitor coupled between the control terminal of the eighth transistor and the second differential output; and
a second capacitor coupled between the control terminal of the ninth transistor and the first differential output.

20. The system of claim 15, further comprising:
a gain control circuit to selectively provide respective switch signals to respective slices of the variable gain amplifier based on an amount of gain to be provided by the variable gain amplifier.
